(19) United States
(12) Patent Application Publication
(10) Pub. No.: US 2007/0184663 A1
(43) Pub. Date: Aug. 9, 2007

(54) Method of planarizing a semiconductor device

(75) Inventors: Jun-Yong Kim, Yongin-si (KR); Ho-Young Kim, Seongnam-si (KR); Chang-Ki Hong, Seongnam-si (KR); Bo-Un Yoon, Seoul (KR); Sung-Ho Shin, Yongin-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/702,124

(22) Filed: Feb. 5, 2007

(30) Foreign Application Priority Data
Feb. 3, 2006 (KR) 10-2006-0010834

(51) Int. Cl. H01L 21/461; H01L 21/302

(52) U.S. Cl. 438/692; 257/E21.304

(57) ABSTRACT

Example embodiments are directed to a method of planarizing a semiconductor device. A first CMP process may be performed on an insulating layer to remove a stepped structure of the insulating layer. A second CMP process may be performed to planarize the insulating layer with the stepped structure removed until a given pattern is exposed. A process temperature of the first CMP process may be higher than that of the second CMP process. Accordingly, an initial stepped structure may be more readily removed in a planarization process of a surface of the semiconductor device, which may reduce the CMP process time and may increase the degree of planarization.

### PRIORITY STATEMENT

This U.S. non-provisional patent application claims priority under 35 U.S.C. § 119 to Korean Patent Application No. 10-2006-10834, filed on Feb. 3, 2006, the entire contents of which are hereby incorporated by reference.

### BACKGROUND

1. Field

Example embodiments relate to a method of forming a semiconductor device, and more particularly, to a method of planarizing a semiconductor device.

2. Description of the Related Art

Semiconductor devices may be approaching ultra large scale integration (ULSI), with dynamic random access memory (DRAM) sizes ranging from 256 MB to 1 GB and beyond leading to higher performance and higher integration. Accordingly, semiconductor devices requiring finer pattern forming techniques and broader regions may necessitate three-dimensional multilayer structures. When fine wiring is multilayered by pattern forming techniques, planarization of an interlayer dielectric (ILD) layer existing thereunder may be required, but only partial planarization has thus far been applied to the ILD layer. However, planarization throughout a wafer, that is, global planarization, may be a practical process to achieve an improvement in processing efficiency and quality of semiconductor devices. This type of planarization is called chemical mechanical polishing (CMP).

A CMP process is a planarization process that may utilize a chemical reaction from a slurry and a mechanical process from a polishing pad. The CMP process may obtain global planarization and may be performed at lower temperatures in comparison to conventional planarization processes; for example, a reflow process or an etch-back process.

When used in a fabrication process for semiconductor devices, CMP processes may be applied to the planarization of an insulating layer, the planarization of metal wiring, and/or the planarization of a trench structure in a device isolation area.

The above features have led to considerable research in CMP equipment, supplies, processes, and process design technology. Since the introduction of CMP processes in the fabrication of semiconductor devices, various developments have been made in device isolating techniques, the realization of fine pattern structures, and the global planarization of semiconductor devices for multilayer wiring, in order to improve the degree of integration.

For example, when used in conjunction with a photolithography process implementing a fine pattern by improving the exposure depth of focus (DOF), a CMP process may make the formation of a multilayer wiring pattern possible. As another example, a CMP process may also be used to reduce a stepped structure between a memory cell region and an adjacent peripheral circuit region in memory devices.

Compared to a conventional silica based slurry, a cerium oxide (CeO₂ or ceria) based slurry may have a high selectivity with respect to a silicon nitride (SiN) layer. Accordingly, the cerium oxide based slurry may be used, for example, in a CMP process for planarization of shallow trench isolations, exposing a silicon oxide (SiO₂) layer, a SiN layer, and/or an interlayer insulating layer.

However, in a CMP process directed at a layer of a single component, the ability to reduce or minimize the loss of a smaller stepped structure region while effectively removing a larger stepped structure region may outweigh any selectivity benefits. In that case, there may not be much difference between the conventional silica based slurry and the cerium oxide based slurry in terms of planarization ability.

A cerium oxide based slurry may be used in a CMP process for selectively removing a silicon oxide layer. When the cerium oxide based slurry is used in a CMP process for removing a silicon oxide layer having a stepped structure on its surface, a loading effect may occur. That is, extra time may be required at the beginning of the process, due to a lower removal rate of the silicon oxide layer. Although, the removal rate of the silicon oxide layer may increase after the initial loading effect and the silicon oxide layer may be subsequently removed more quickly. However, the CMP process may take a longer time overall and hence the throughput may be negatively impacted, which may lead to increased costs.

### SUMMARY

Example embodiments are directed to a method of planarizing a semiconductor device.

According to example embodiments, a first CMP process may be performed on an insulating layer to remove a stepped structure of the insulating layer, and a second CMP process may be performed to planarize the insulating layer with the stepped structure removed until a given pattern is exposed. The process temperature of the first CMP process may be higher than that of the second CMP process. A desired pattern with a stepped structure may be formed on a semiconductor substrate prior to a CMP process; an insulating layer that covers the semiconductor substrate including the desired pattern may also be formed prior to a CMP process. Accordingly, an initial stepped structure may be more easily removed in a planarization process of a surface of the semiconductor device, which may reduce a CMP process time and may increase the degree of planarization.

According to example embodiments, an upper surface of the desired pattern with the stepped structure may include a polish stop layer. The polish stop layer may be formed of silicon nitride having a lower etch rate than the insulating layer.

According to example embodiments, the insulating layer may be formed of silicon oxide.

According to example embodiments, the first CMP process may use a slurry having a higher selectivity than the insulating layer in comparison to the given pattern. The slurry may be a cerium oxide based slurry.

According to example embodiments, the first CMP process may be performed at a process temperature above 25° C. The process temperature may be adjusted by heating the slurry, the cleaning solution for the polishing pad, or the CMP apparatus itself.

According to example embodiments, the second CMP process may use the same slurry as that used in the first CMP process. The slurry may be a cerium oxide based slurry.

According to example embodiments, the second CMP process may be performed at a process temperature below 25° C. The process temperature may be adjusted by cooling the slurry, the cleaning solution for the polishing pad, or the CMP apparatus itself.

According to example embodiments, each of the first and second CMP processes may be performed on separate polishing pads. The polishing pad on which the first CMP process is performed may be maintained at a temperature above 25° C., and the polishing pad on which the second CMP process is performed may be maintained at a temperature below 25° C.

### BRIEF DESCRIPTION OF THE DRAWINGS

The above and other features and advantages of example embodiments will become more apparent by describing in detail example embodiments with reference to the attached drawings. The accompanying drawings are intended to depict example embodiments and should not be interpreted to limit the intended scope of the claims. The accompanying drawings are not to be considered as drawn to scale unless explicitly noted.

FIG. 1 is a graph illustrating example removal rates of a silicon oxide layer by a CMP process at multiple process temperatures.

FIG. 2 is a graph illustrating example removal rates of a silicon nitride layer by a CMP process at multiple process temperatures.

FIG. 3 is a graph illustrating example changes in a polishing amount of a silicon oxide layer that covers a given pattern by a CMP process at multiple process temperatures.

FIG. 4 is a graph illustrating example degrees of etching of a stepped structure, formed on a surface of a semiconductor substrate, under a CMP process at multiple process temperatures.

FIGS. 5A through 5F are cross-sectional views illustrating a method of planarizing a semiconductor device according to example embodiments.

### DESCRIPTION OF EXAMPLE EMBODIMENTS

Detailed example embodiments are disclosed herein. However, specific structural and functional details disclosed herein are merely representative for purposes of describing example embodiments. Example embodiments may, however, be embodied in many alternate forms and should not be construed as limited to only the embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but to the contrary, example embodiments are to cover all modifications, equivalents, and alternatives falling within the scope of example embodiments. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved. It will also be understood that when a layer (or film) is referred to as being ‘on’ another layer or substrate, it may be directly on the other layer or substrate, or intervening layers may also be present.

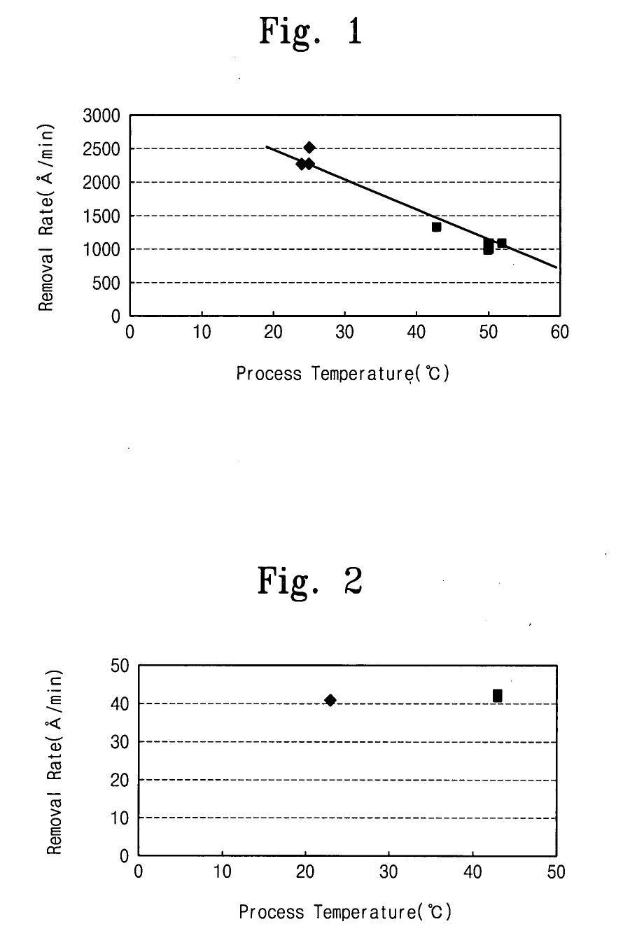

FIG. 1 is a graph illustrating example removal rates of a silicon oxide layer at multiple process temperatures in a CMP process.

Referring to FIG. 1, when a silicon oxide layer formed on a semiconductor substrate without a stepped structure is etched by a CMP process using a cerium oxide based slurry, the removal rate of the silicon oxide layer may vary according to the process temperature. The removal rate may be approximately 2300 Å/min at about 25° C. (corresponding to a lower temperature region), while the removal rate may be approximately 1200 Å/min at about 50° C. (corresponding to a higher temperature region). As FIG. 1 shows, when the silicon oxide layer is etched by a CMP process using a cerium oxide based slurry, the removal rate may increase as the process temperature becomes lower.

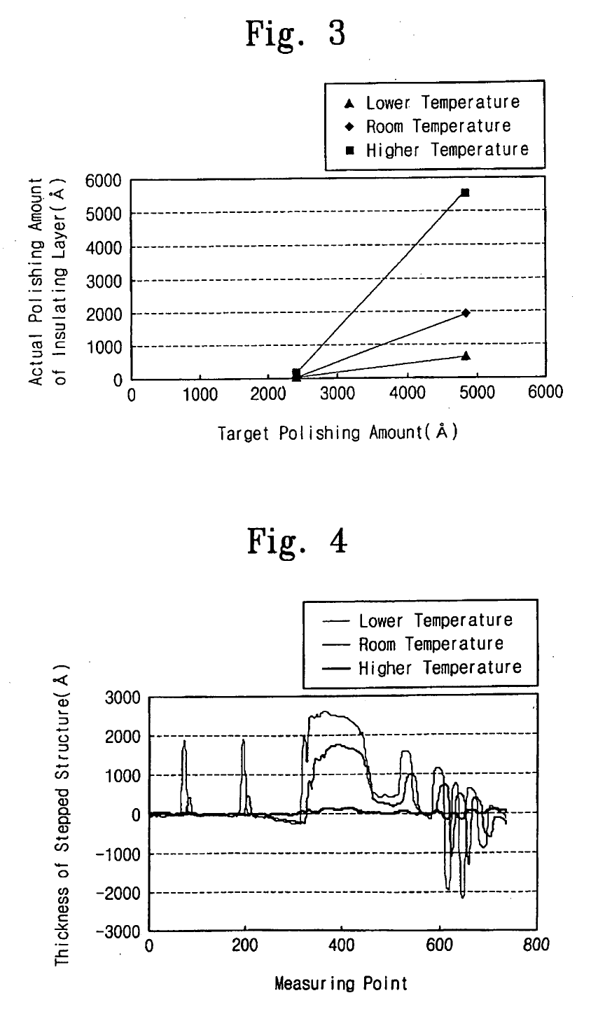

FIG. 2 is a graph illustrating example removal rates of a silicon nitride layer at multiple process temperatures in a CMP process.

Referring to FIG. 2, when a silicon nitride layer formed on a semiconductor substrate without a stepped structure is etched by a CMP process using a cerium oxide based slurry, the removal rate of the silicon nitride layer may be maintained constant, regardless of process temperature. The removal rate may be approximately 41 Å/min at about 23° C. (corresponding to a lower temperature region), while the removal rate may be approximately 43 Å/min at about 43° C. (corresponding to a higher temperature region).

As can be seen from the graphs in FIGS. 1 and 2, the etching selectivity of the silicon oxide layer with respect to the silicon nitride layer may increase as the process temperature in a CMP process using a cerium oxide based slurry decreases. In general, the silicon oxide layer may be used as an insulating layer in a semiconductor device, while the silicon nitride layer may be used as an etch stop.

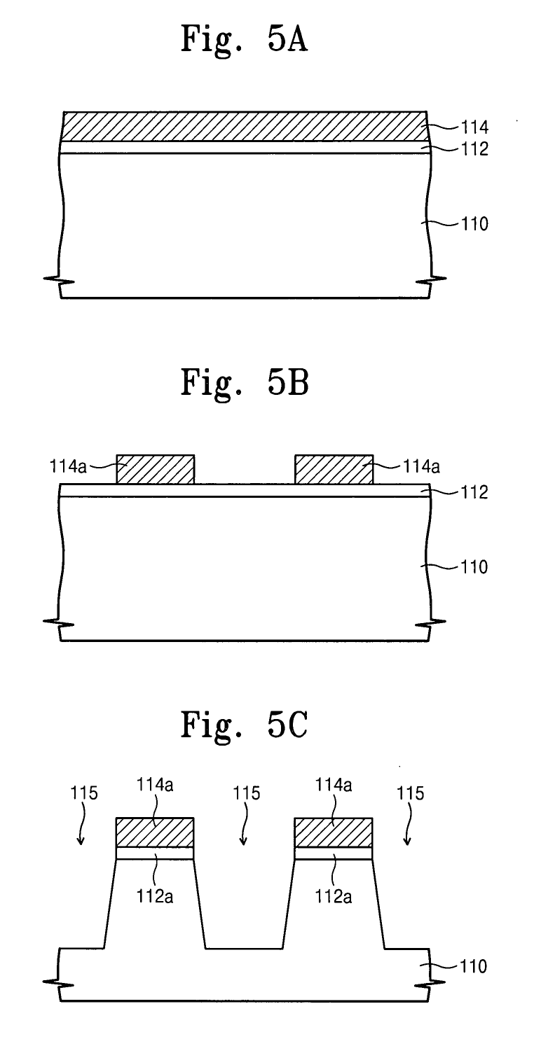

FIG. 3 is a graph illustrating example changes in polishing amount at multiple CMP process temperatures of a silicon oxide layer that covers a given pattern.

Referring to FIG. 3, when a silicon oxide layer having no stepped structure and a thickness of approximately 2400 Å, and that covers a pattern with a given stepped structure formed on a semiconductor substrate, is etched by a CMP process, the silicon oxide layer may show little etching at lower process temperatures (for example, 20° C.), room process temperatures (for example, 25° C.), or higher process temperatures (for example, 50° C.). On the other hand, when a silicon oxide layer having a pronounced stepped structure and a thickness of approximately 4900 Å, and that covers a pattern with a given stepped structure formed on a semiconductor substrate, is etched by a CMP process, the silicon oxide layer may be etched approximately 700 Å at lower process temperatures, approximately 1900 Å at room process temperatures, and approximately 5500 Å at higher process temperatures.

Accordingly, when the silicon oxide layer with a given stepped structure formed on a semiconductor substrate is etched by a CMP process using a cerium oxide based slurry, the stepped structure may be easily removed by performing an initial process at a higher process temperature.

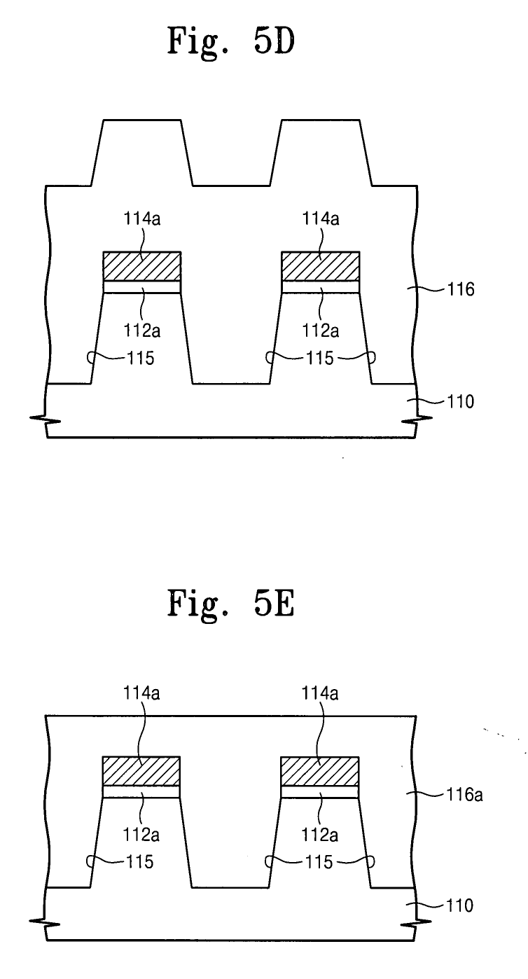

FIG. 4 is a graph illustrating example degrees of planarization of a stepped structure formed on a surface of a semiconductor substrate according to various process temperatures in a CMP process.

Referring to FIG. 4, when a silicon oxide layer that covers a pattern with a given stepped structure, formed on a semiconductor substrate, is etched by a CMP process using a cerium oxide based slurry, the degree of surface planarization may vary according to the process temperature. The stepped structure may show little etching at lower process temperatures (for example, 20° C.), may show moderate etching at room process temperatures (for example, 25° C.), and may be almost completely removed at higher process temperatures (for example, 50° C.).

Accordingly, when a silicon oxide layer that covers a pattern with a large stepped structure, formed on a semiconductor substrate, is etched by a CMP process using a cerium oxide based slurry, it may be beneficial to remove the stepped structure beforehand. That is, the surface of the semiconductor substrate may be planarized more uniformly by performing an initial CMP process at a higher process temperature.

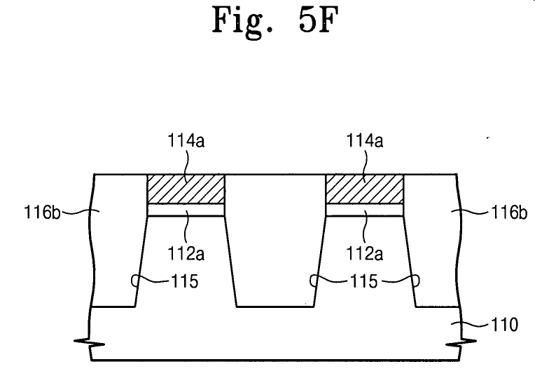

FIGS. 5A through 5F are cross-sectional views illustrating a method of planarizing a semiconductor device according to example embodiments.

Referring to FIG. 5A, a pad oxide layer 112 may be formed on a semiconductor substrate 110. The pad oxide layer 112 may be formed by a thermal oxidation process and/or a natural oxidation process, with a thickness of approximately 30 to 200 Å.

A polish stop layer 114 may be formed on the pad oxide layer 112. The polish stop layer 114 may be a silicon nitride layer deposited by a chemical vapor deposition (CVD) process. The polish stop layer 114 may be formed with a thickness of approximately 200 to 800 Å. The pad oxide layer 112 may be formed between the polish stop layer 114 and the semiconductor substrate 110 in order to alleviate any stress to the semiconductor substrate layer 10 that would be caused if, for example, a silicon nitride layer to be used as the polish stop layer 114 were directly formed on the semiconductor substrate 110.

Referring to FIG. 5B, a photoresist pattern (not shown) may be formed on the polish stop layer 114. The polish stop layer 114 may then be etched using the photoresist pattern as a mask in order to form a mask pattern 114a out of the polish stop layer 114. At this point, the pad oxide layer 112 may be exposed in a device isolation region.

Referring to FIG. 5C, the exposed pad oxide layer 112 and the semiconductor substrate 110 may be etched using the mask pattern 114a to form trenches 115. The trenches 115 may be formed with a depth of approximately 2000 to 6000 Å.

Referring to FIG. 5D, an insulating layer 116 may be formed to fill the trenches 115 and cover the semiconductor substrate 110. The insulating layer 116 may be a silicon oxide layer deposited by a CVD process; for example, it may be a TetraEthyl OrthoSilicate (TEOS) layer deposited by a plasma enhanced CVD (PE-CVD) process.

The insulating layer 116 may fill the trenches 115, and thus may be formed thicker than at least the depth of the trenches 115. For example, the insulating layer 116 may be formed thicker than the depth of the trenches 115 by approximately 1000 to 5000 Å. This may ensure compliance with required process margins and prevent the insulating layer 116 filling the trenches 115 from being dished in a subsequent process. The insulating layer 116 may have a stepped structure in-between where the trenches 115 are formed in the semiconductor substrate 110.

Referring to FIG. 5E, the semiconductor substrate 110 on which the insulating layer 116 with the stepped structure is formed may be mounted on a polishing pad of a CMP apparatus and etched by a first CMP process to form an insulating layer 116a with the stepped structure removed.

The first CMP process may use a slurry having a higher selectivity with respect to the insulating layer 116 than the mask pattern 114a. For example, if the insulating layer 116 is a silicon oxide layer, the slurry may be a cerium oxide based slurry. Also, the first CMP process may be performed at a higher process temperature, for example, over 25° C. The higher process temperature may be adjusted by heating the slurry, the cleaning solution for the polishing pad, or the CMP apparatus itself. Accordingly, loading times that may lead to excessive CMP processing time due to an initial stepped structure may be reduced.

The insulating layer 116a as shown in FIG. 5E, with the stepped structure removed, may be etched by a second CMP process to form device isolation layers 116b as shown in FIG. 5F.

The second CMP process may use the same slurry as that used in the first CMP process, which, for example, may be a cerium oxide based slurry. Also, the second CMP process may be performed at a lower process temperature, for example, below 25° C. The lower process temperature may be adjusted by cooling the slurry, the cleaning solution for the polishing pad, or the CMP apparatus itself. Accordingly, the selectivity of the insulating layer 116a with the stepped structure removed formed of a silicon oxide layer becomes higher than that with respect to the mask pattern 114a formed of a silicon nitride layer, which may reduce the CMP process time.

The first and second CMP processes may be performed on separate polishing pads so as to reduce the time necessary for heating and cooling the slurry, the cleaning solution, and/or the CMP apparatus itself. Accordingly, the polishing pad on which the first CMP process may be performed may maintain a higher process temperature, for example, over 25° C., and the polishing pad on which the second CMP process may be performed may maintain a lower process temperature, for example, below 25° C.

Thus, the CMP process time may be reduced and the degree of planarization may be increased by planarizing the semiconductor device according to example embodiments. Example embodiments may remove the initial stepped structure in a planarization process of an insulating layer that covers the semiconductor device with a given stepped structure.

As described above, according to example embodiments, the initial stepped structure may be more readily removed by changing the process temperature in the planarization process of the insulating layer that covers the semiconductor device with a given stepped structure. Thus, the CMP process time can be reduced and the degree of planarization can be increased.

Example embodiments having thus been described, it will be obvious that the same may be varied in many ways. Such variations are not to be regarded as a departure from the intended spirit and scope of example embodiments, and all such modifications as would be obvious to one skilled in the art are intended to be included within the scope of the following claims.

What is claimed is:

1. A method of planarizing a semiconductor device, the method comprising:
performing a first CMP (chemical mechanical polishing) process on an insulating layer to remove a stepped structure of the insulating layer; and
performing a second CMP process to planarize the insulating layer with the stepped structure removed until a given pattern is exposed,
wherein a process temperature of the first CMP process is higher than a process temperature of the second CMP process.

2. The method of claim 1, further comprising:
forming the given pattern with the stepped structure on a semiconductor substrate; and
forming the insulating layer that covers the semiconductor substrate including the given pattern.

3. The method of claim 2, wherein an upper surface of the given pattern with the stepped structure includes a polish stop layer.

4. The method of claim 3, wherein the polish stop layer is formed of a material having a lower etch rate with respect to the insulating layer.

5. The method of claim 3, wherein the polish stop layer is formed of silicon nitride.

6. The method of claim 2, wherein the insulating layer is formed of silicon oxide.

7. The method of claim 1, wherein the first CMP process uses a slurry having a higher selectivity with respect to the insulating layer in comparison to the given pattern.

8. The method of claim 7, wherein the slurry is a cerium oxide based slurry.

9. The method of claim 1, wherein the first CMP process is performed at a process temperature above 25° C.

10. The method of claim 9, wherein the process temperature of the first CMP process is adjusted by heating a slurry.

11. The method of claim 9, wherein the process temperature of the first CMP process is adjusted by heating a cleaning solution for a polishing pad.

12. The method of claim 9, wherein the process temperature of the first CMP process is adjusted by heating a CMP apparatus.

13. The method of claim 1, wherein the second CMP process is performed at a process temperature below 25° C.

14. The method of claim 13, wherein the process temperature of the second CMP process is adjusted by cooling a slurry.

15. The method of claim 13, wherein the process temperature of the second CMP process is adjusted by cooling a cleaning solution for a polishing pad.

16. The method of claim 13, wherein the process temperature of the second CMP process is adjusted by cooling a CMP apparatus.

17. The method of claim 1, wherein the second CMP process uses the same slurry as that used in the first CMP process.

18. The method of claim 17, wherein the slurry is a cerium oxide based slurry.

19. The method of claim 1, wherein the first and second CMP processes are performed with separate polishing pads.

20. The method of claim 19, wherein the polishing pad with which the first CMP process is performed is maintained at a temperature above 25° C.

21. The method of claim 19, wherein the polishing pad with which the second CMP process is performed is maintained at a temperature below 25° C.
